(19) United States
(12) Patent Application Publication
(10) Pub. No.: US 2020/0113089 A1
(43) Pub. Date: Apr. 9, 2020

(54) MODULE DEVICE AND METHOD FOR ASSEMBLING MODULE DEVICE

(71) Applicant: NIHON DEMPA KOGYO CO., LTD., Tokyo (JP)

(72) Inventors: Tomoya YORITA, Saitama (JP); Youhei NAKAJIMA, Saitama (JP); Hiroki KIMURA, Saitama (JP)

(73) Assignee: NIHON DEMPA KOGYO CO., LTD., Tokyo (JP)

(21) Appl. No.: 16/591,629

(22) Filed: Oct. 3, 2019

(30) Foreign Application Priority Data
Oct. 5, 2018 (JP) 2018-189877
Mar. 11, 2019 (JP) 2019-043267

(51) Int. Cl. H05K 9/00

(52) U.S. Cl. CPC H05K 9/0018; H05K 9/0009

(57) ABSTRACT

A module device includes a substrate, an upper-side case, a lower-side case, and an auxiliary member. The upper-side case has a first wall and covers at least a part of a first surface of the substrate. The lower-side case has a second wall that extends to the substrate and is in contact with the substrate. The lower-side case covers at least a part of a second surface on a side opposite to the first surface of the substrate. The auxiliary member assists an electrical connection between the second wall and at least one of the substrate and the first wall. The upper-side case is fitted to the lower-side case across the substrate to house at least a part of the substrate.

### CROSS-REFERENCE TO RELATED APPLICATIONS

This application is based on and claims priority under 35 U.S.C. § 119 to Japanese Patent Application No. 2018-189877 filed on Oct. 5, 2018 and Japanese Patent Application No. 2019-043267 filed on Mar. 11, 2019, the entire contents of which are incorporated herein by reference.

### TECHNICAL FIELD

This disclosure relates to a module device and a method for assembling the module device.

### DESCRIPTION OF THE RELATED ART

Conventionally, a module device or the like where a ground wiring of a substrate on which an electronic circuit has been disposed is electrically connected to a case that houses this substrate has been known (for example, see Japanese Unexamined Patent Application Publication No. 2003-258453 and Japanese Unexamined Utility Model Application Publication No. 62-160599).

Such a substrate sometimes includes devices where high frequency signals are handled, such as A/D converters, D/A converters, mixers, and amplifiers, on both surfaces. In this case, a component for shield will be mounted on each of a front surface and a back surface of the substrate. When a component with a simple assembly was employed as such a shield component, it has happened that the high frequency signal leaks out from a gap or the like on a substrate end surface to cause the signal to interfere between a plurality of transmission channels. It has also happened that a shield component having an improved shield property makes its assembly complicated to reduce a productivity of a product.

A need thus exists for a module device and a method for assembling the module device which are not susceptible to the drawback mentioned above.

### SUMMARY

According to a first aspect of this disclosure, there is provided a module device that includes a substrate, an upper-side case, a lower-side case, and an auxiliary member. The upper-side case has a first wall and covers at least a part of a first surface of the substrate. The lower-side case has a second wall that extends to the substrate and is in contact with the substrate. The lower-side case covers at least a part of a second surface on a side opposite to the first surface of the substrate. The auxiliary member assists an electrical connection between the second wall and at least one of the substrate and the first wall. The upper-side case is fitted to the lower-side case across the substrate to house at least a part of the substrate.

### BRIEF DESCRIPTION OF THE DRAWINGS

The foregoing and additional features and characteristics of this disclosure will become more apparent from the following detailed description considered with reference to the accompanying drawings, wherein:

FIG. 1 illustrates an exemplary configuration of a module device 100 according to the embodiment;

FIG. 2 illustrates an exemplary electric signal processed by the module device 100 according to the embodiment;

FIG. 3 illustrates an exemplary configuration of a first shield case 122 of the module device 100 according to the embodiment;

FIG. 4 illustrates a first exemplary configuration of the first shield case 122 according to the embodiment;

FIG. 5 illustrates an exemplary configuration of a lower-side case 220 of the first shield case 122 having the first exemplary configuration according to the embodiment;

FIG. 6 illustrates a second exemplary configuration of the first shield case 122 according to the embodiment;

FIG. 7 illustrates a third exemplary configuration of the first shield case 122 according to the embodiment;

FIG. 8 illustrates an exemplary electric signal processed by the module device 100 that includes an auxiliary member 230 according to the embodiment;

FIG. 9 illustrates a fourth exemplary configuration of the first shield case 122 according to the embodiment;

FIG. 10 illustrates an exemplary flow for assembling the module device 100 that includes the first shield case 122 having the fourth exemplary configuration;

FIG. 11 illustrates an exemplary configuration of a cross section in a state where the lower-side case 220 has been mounted on a substrate 110 according to the embodiment;

FIG. 12 illustrates an exemplary configuration of a cross section in a state where a conductive member has been mounted on the substrate 110 and the lower-side case 220 according to the embodiment; and

FIG. 13 illustrates an exemplary configuration of a cross section in a state where an upper-side case 210 has been mounted on the substrate 110 and the lower-side case 220 according to the embodiment.

### DETAILED DESCRIPTION

### Exemplary Configuration of Module Device 100

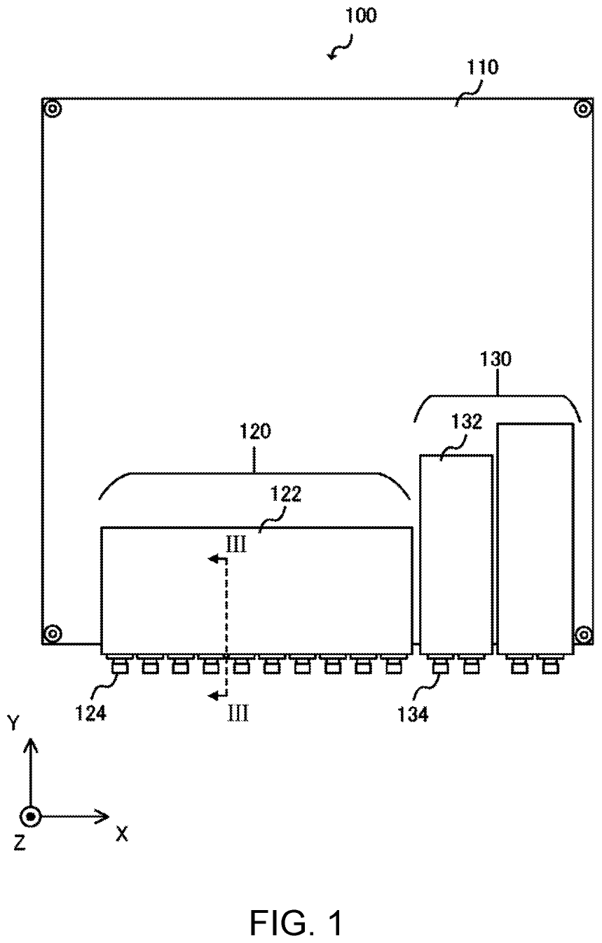

FIG. 1 illustrates an exemplary configuration of a module device 100 according to the embodiment. FIG. 1 illustrates an exemplary first surface as a front surface of the module device 100. In FIG. 1, the first surface is assumed to be a surface approximately parallel to an X-Y plane. The module device 100 is, for example, a module device that transmits and receives a high frequency signal of around a few GHz to ten-odd GHz. The module device 100 includes a substrate 110, a receiver 120, and a transmitter 130.

The substrate 110 is a double-sided mounting substrate where electronic components, wirings, and the like are disposed on a first surface and a second surface on a side opposite to the first surface to constitute electronic circuits. For example, a receiving circuit, which receives an electric signal, and a transmitting circuit, which transmits the electric signal, are configured on the substrate 110. The substrate 110 is a single-layer or multi-layer substrate. The substrate 110 has the first surface and the second surface on the side opposite to the first surface on which the electronic components, the wirings, and the like are disposed.

The receiver 120 receives the electric signal from outside. The receiver 120 receives, for example, the high frequency signal of a few GHz to around ten-odd GHz. The receiver 120 includes, for example, an A/D converter that converts a received analog signal into a digital signal. Instead of this, the receiver 120 may include a D/A converter that converts a received digital signal into an analog signal. The receiver 120 may include a down conversion circuit that converts a received high frequency signal into a signal having a frequency lower than that of this high frequency signal. In the receiver 120, the component and the wiring, which handle the high frequency signals, are susceptible to noise or the like from outside and likely to generate the noise to the outside. Thus, the component and the wiring are preferably blocked by an electromagnetic shield.

FIG. 1 illustrates an example that the receiver 120 includes a first shield case 122. The first shield case 122 is a metallic case that is electrically connected to a ground potential of the substrate 110 and covers the component and the wiring that handles the high frequency signals. FIG. 1 illustrates an example that the first shield case 122 includes one or a plurality of input connectors 124. The input connector 124 is preferably a normalized connector. The input connector 124 is, for example, a Sub Miniature Type A (SMA) connector or the like. FIG. 1 illustrates an example that the receiver 120 includes a plurality of input connectors 124 for receiving the high frequency signal and a clock signal from outside.

The transmitter 130 transmits the electric signal to the outside. The transmitter 130 transmits, for example, the high frequency signal of a few GHz to around ten-odd GHz. The transmitter 130 includes, for example, a D/A converter that converts the digital signal handled in the substrate 110 into an analog signal. The transmitter 130 may include an A/D converter that converts the analog signal handled in the substrate 110 into a digital signal. The transmitter 130 may include an up conversion circuit that performs conversion into a high frequency signal having a frequency higher than a signal frequency handled in the substrate 110. In the transmitter 130, the component and the wiring, which handle the high frequency signals, are preferably blocked by the electromagnetic shield, similarly to the receiver 120.

FIG. 1 illustrates an example that the transmitter 130 includes a second shield case 132. The second shield case 132 is a metallic case that is electrically connected to the ground potential of the substrate 110 and covers the component and the wiring that handles the high frequency signals. FIG. 1 illustrates an example that the second shield case 132 includes one or a plurality of output connectors 134. The output connector 134 is preferably a normalized connector such as the SMA connector. FIG. 1 illustrates an example that the transmitter 130 includes a plurality of output connectors 134 for transmitting the high frequency signal and a clock signal to the outside.

As described above, in the module device 100 illustrated in FIG. 1, as one example, a circuit in a region that is not shielded in the electronic circuits disposed on the substrate 110 processes the digital signal having a frequency lower than that of the analog signal in a shielded region. A shielded circuit in the electronic circuits disposed on the substrate 110 is included in the receiver 120 or the transmitter 130. The receiver 120 receives the high frequency signal from outside to convert it into the digital signal having a lower frequency. The transmitter 130 converts the digital signal processed by the substrate 110 into an analog high frequency signal having a higher frequency to transmit it to the outside. Such an electric signal processed by the module device 100 will be described next.

### Exemplary Signal Inside Receiver 120 of Module Device 100

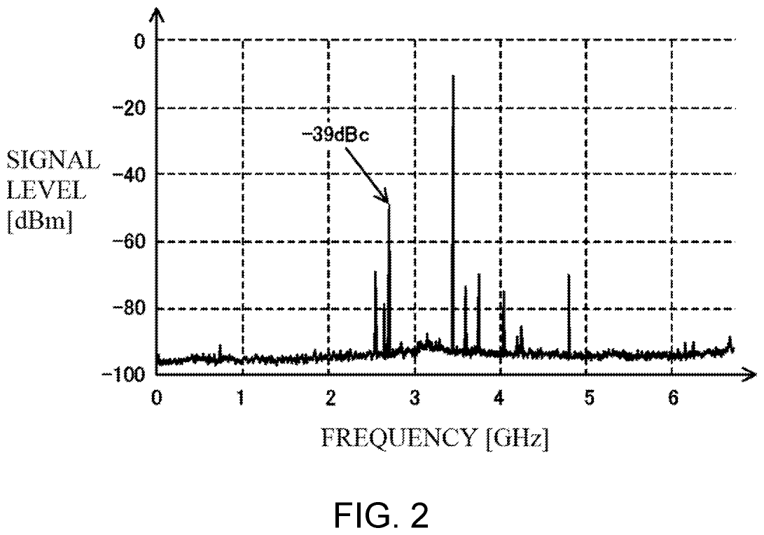

FIG. 2 illustrates an exemplary electric signal processed by the module device 100 according to the embodiment. FIG. 2 illustrates an exemplary result from a reception of the high frequency signal of 3.45 GHz by the receiver 120. FIG. 2 illustrates an example that the receiver 120 receives the clock signal of 4.8 GHz. FIG. 2 illustrates an exemplary result from a frequency analysis with a spectrum analyzer or the like of the analog signal after the reception by the receiver 120. In FIG. 2, the horizontal axis indicates a frequency, and the vertical axis indicates a signal strength.

It can be seen that a plurality of spurious components are superimposed on a frequency spectrum illustrated in FIG. 2, besides the high frequency signal of 3.45 GHz. They are a folding component as a result of an interference of a second harmonic component of the high frequency signal of 3.45 GHz with the clock signal of 4.8 GHz, a leakage component of the clock signal of 4.8 GHz, and the like. It can be seen that the signal strength of a spurious generated at 2.7 GHz among the plurality of spurious components is relatively high, −39 dBc with respect to the signal strength of the high frequency signal of 3.45 GHz. Thus, simply shielding the high frequency circuit may generate a plurality of spuriouses.

Such a spurious may cause malfunction in signal processing in the substrate 110 or may cause radio disturbance when the spurious is superimposed on a transmission signal of the transmitter 130. Especially, the spurious of −39 dBc generated at 2.7 GHz does not satisfy a spurious standard. Thus, the module device 100 is required to take a countermeasure such as improvement in a shield performance. Therefore, the shield case of the module device 100 will be described next.

### Exemplary Configuration of First Shield Case 122

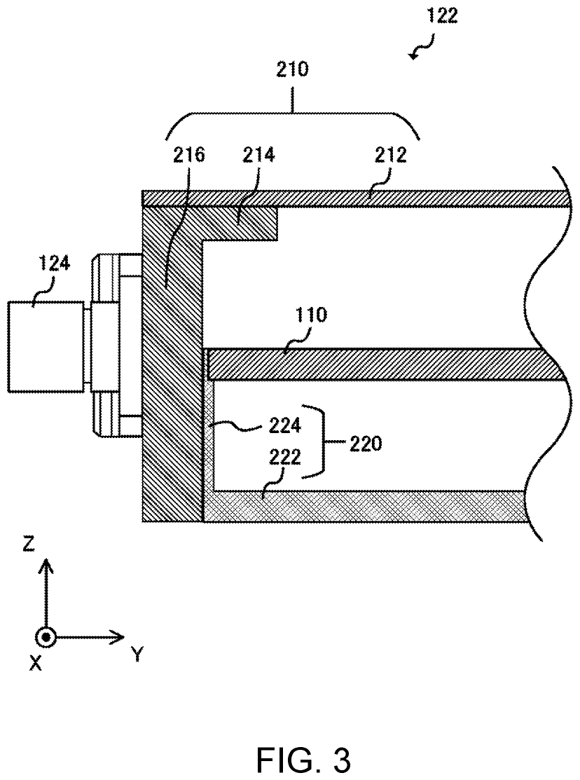

FIG. 3 illustrates an exemplary configuration of the first shield case 122 of the module device 100 according to the embodiment. FIG. 3 illustrates an exemplary configuration of a cross section taken along the line III-III of the receiver 120 illustrated in FIG. 1. The first shield case 122 includes an upper-side case 210 and a lower-side case 220.

The upper-side case 210 covers at least a part of the first surface of the substrate 110. The upper-side case 210 is formed, for example, to surround a partial region including the electronic component and the wiring on the substrate 110 over the first surface of the substrate 110. The upper-side case 210 has a lid 212, a first main body 214, and a first wall 216.

The lid 212 is a plate-shaped member arranged approximately parallel to the substrate 110. The lid 212 is fixed to the first main body 214 with a screw or the like. The first main body 214 has, for example, a shape having an opening on an X-Y surface to surround a region on which the electronic component, the wiring, and the like on the substrate 110 are mounted. In this case, the opening of the first main body 214 is blocked by the lid 212. The first main body 214 is preferably formed such that its outer wall has a square shape on the X-Y surface.

The first wall 216 is integrally formed with the first main body 214 on an end portion of the first main body 214. The first wall 216 is formed as a part of the outer wall of the first main body 214. FIG. 3 illustrates an example that the first wall 216 has been formed as a part of the outer wall on a −Y-direction side of the first main body 214. The first wall 216 extends to a side of the second surface of the substrate 110 on an end portion of the upper-side case 210. The first wall 216 is formed, for example, to extend in a −Z direction to be in contact with the lower-side case 220. The input connector 124 is fixed to the first wall 216 with a screw or the like.

The lower-side case 220 covers at least a part of the second surface on the side opposite to the first surface of the substrate 110. The lower-side case 220 is formed, for example, to surround a partial region including the electronic component and the wiring mounted on the substrate 110 on the second surface side of the substrate 110. The lower-side case 220 has a second main body 222 and a second wall 224.

The second main body 222 has, for example, a shape having a depressed portion to surround a region on which the electronic component, the wiring, and the like are mounted on the second surface side of the substrate 110. In this case, the second main body 222 is fixed to the substrate 110 to block a space inside this depressed portion. The second main body 222 is preferably formed such that its outer wall has a square shape on an X-Y surface.

The second wall 224 is integrally formed with the second main body 222 on an end portion of the second main body 222. The second wall 224 is formed as a part of the outer wall of the second main body 222. FIG. 3 illustrates an example that the second wall 224 has been formed as a part of the outer wall on a −Y-direction side of the second main body 222. The second wall 224 extends toward the substrate 110 to be in contact with the substrate 110 on an end portion of the lower-side case 220.

In the above-described module device 100 according to the embodiment, the upper-side case 210 is fitted to the lower-side case 220 across the substrate 110 to house at least a part of the substrate 110. For example, the substrate 110 is placed on the lower-side case 220, and the lower-side case 220 is fixed to the substrate 110 with a screw or the like from a side of the first surface of the substrate 110. Thus, at least a part of the second surface side of the substrate 110 is blocked by the lower-side case 220. Then, the upper-side case 210 is fitted to the lower-side case 220 from the first surface side of the substrate 110 to be fixed to the lower-side case 220 with a screw or the like. Thus, at least a part of the first surface side of the substrate 110 is blocked by the upper-side case 210.

In such a module device 100, while the components that handle high frequency signals are mounted on both surfaces of the substrate 110, the upper-side case 210 and the lower-side case 220 that shield these components can be easily assembled. However, in such a module device 100, the high frequency signal may leak out from gaps or the like of the upper-side case 210, the lower-side case 220, and the substrate 110.

In this case, it is thought that a countermeasure is taken by mounting conductive tapes, gaskets, conductive cushion structures, or the like on contact parts or the like of the substrate 110, the upper-side case 210, and the lower-side case 220 in the module device 100. Mounting the conductive tapes or the like at appropriate positions can improve a shield property of the module device 100.

However, even in the module device 100 thus assembled, as illustrated in FIG. 2, the spurious may be generated. Even if the countermeasure is taken using the conductive tapes or the like, due to an age deterioration or the like, the shield property may be reduced in the future. The use of such conductive tapes or the like needs confirmation of appropriate positions on which they are mounted by devices, thus taking time and effort in an assembly process. Even if the conductive tapes or the like are used, variation in characteristics after the assembly may occur. Therefore, the module device 100 in the embodiment includes an auxiliary member to improve the shield property inside the first shield case 122. Such a module device 100 will be described next.

### First Exemplary Configuration of Auxiliary Member 230

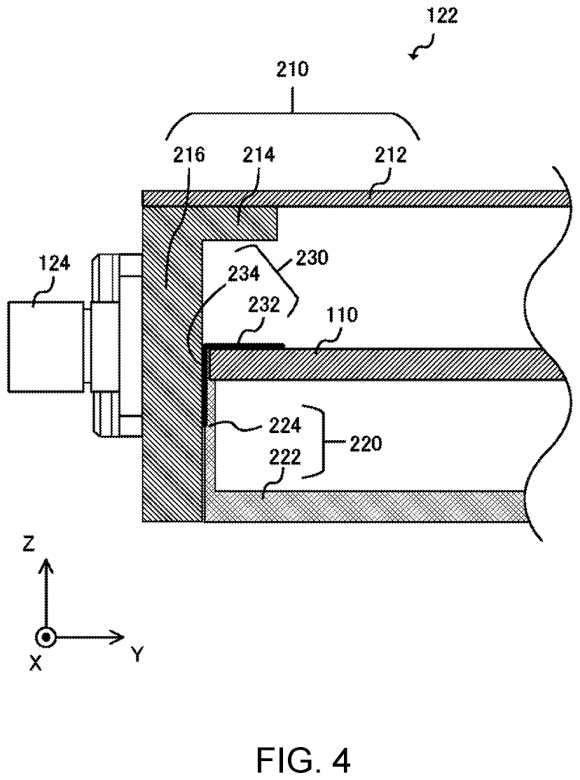

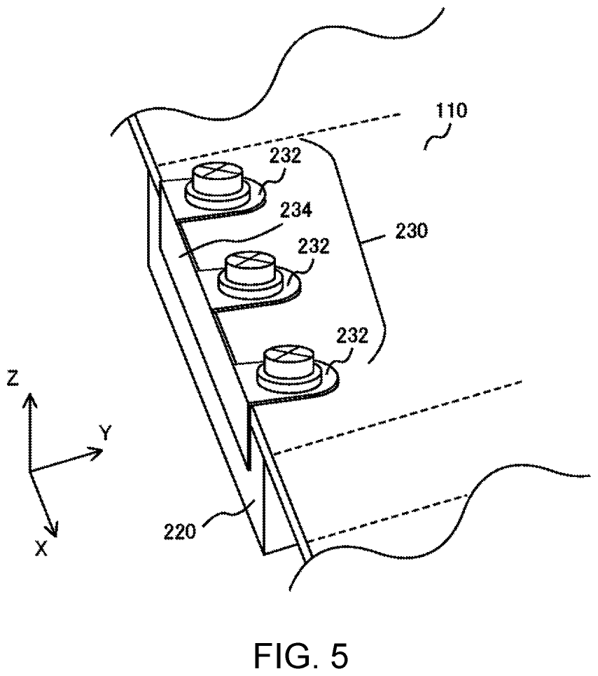

FIG. 4 illustrates a first exemplary configuration of the first shield case 122 according to the embodiment. FIG. 5 illustrates an exemplary configuration of the lower-side case 220 of the first shield case 122 having the first exemplary configuration according to the embodiment. In the first shield case 122 having the first exemplary configuration illustrated in FIG. 4 and FIG. 5, identical reference numerals are attached to ones having operations approximately identical to those of the first shield case 122 illustrated in FIG. 3. Therefore, the description will be omitted. The first shield case 122 having the first exemplary configuration further includes an auxiliary member 230.

The auxiliary member 230 assists an electrical connection between at least one of the substrate 110 and the first wall 216, and the second wall 224. The auxiliary member 230 is made of a conductive material. The auxiliary member 230 contains, for example, copper. The auxiliary member 230 has a first member 232 and a second member 234.

The first member 232 is disposed in contact with the first surface of the substrate 110. The first member 232, as one example, at least partially has a shape of a lug terminal having an opening. In this case, the first member 232 is fixed to the substrate 110 with a screw or the like that passes through this opening. The first member 232 has, for example, a plurality of such lug-terminal shapes. The first member 232 is electrically connected to a ground wiring of the first surface of the substrate 110.

The second member 234 is disposed in contact with the second wall 224. The second member 234 is a plate-shaped member formed parallel to the second wall 224. The second member 234 may be formed to be inclined in the Z direction so that an elastic force acts in the −Y direction when the second member 234 is pressed in the Y direction on a side of the second wall 224. The second member 234 is pressed and fixed to the second wall 224 to be electrically connected to the lower-side case 220.

The above-described first member 232 and second member 234, in a cross section of a surface approximately parallel to a Y-Z plane, have an L-shaped integrated shape. The first member 232 and the second member 234 are integrally formed, for example, by folding one copper plate. Such an auxiliary member 230 can reinforce the electrical connection between the ground wiring on the first surface side of the substrate 110 and the lower-side case 220. The auxiliary member 230 is arranged in a gap between the upper-side case 210 and the lower-side case 220 by fitting the upper-side case 210 to the lower-side case 220. Thus, the auxiliary member 230 can reinforce the electrical connection between the ground wiring on the first surface side of the substrate 110, the upper-side case 210, and the lower-side case 220.

An example that the above-described module device 100 according to the embodiment reinforces the connection of the ground potential between the substrate 110, the upper-side case 210, and the lower-side case 220 using the auxiliary member 230 to improve the shield property has been described. However, the auxiliary member 230 is not limited to the exemplary configuration in FIG. 4 and FIG. 5. Another example of the auxiliary member 230 will be described next.

### Second Exemplary Configuration of Auxiliary Member 230

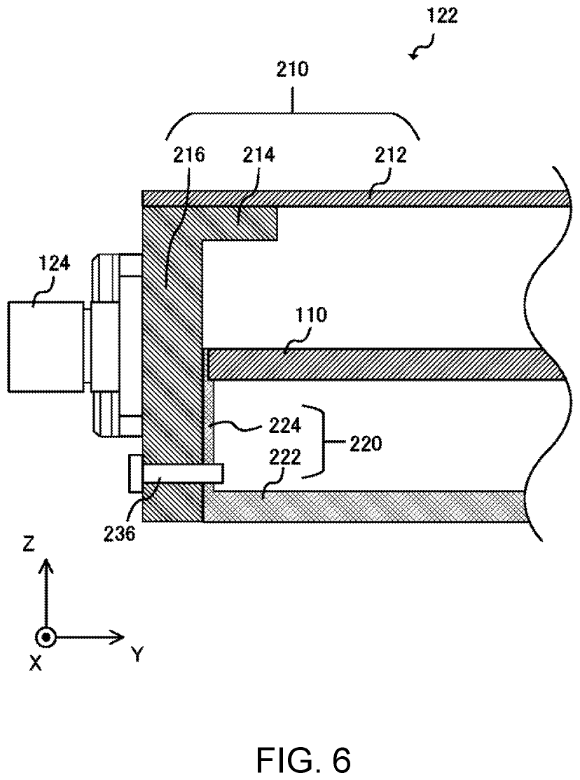

FIG. 6 illustrates a second exemplary configuration of the first shield case 122 according to the embodiment. In the first shield case 122 having the second exemplary configuration illustrated in FIG. 6, identical reference numerals are attached to ones having operations approximately identical to those of the first shield case 122 illustrated in FIG. 3. Therefore, the description will be omitted. An example that the first shield case 122 having the second exemplary configuration includes a conductive third member 236 as the auxiliary member 230 will be described.

The third member 236 couples the first wall 216 to the second wall 224. The third member 236 is, for example, a screw that passes through the first wall 216 and the second wall 224. Such an auxiliary member 230 can reinforce the electrical connection between the upper-side case 210 and the lower-side case 220.

The first wall 216 is preferably partially parallel to the second wall 224. This can more increase an area where the first wall 216 is in close contact with the second wall 224 in a state where the third member 236 has coupled the first wall 216 to the second wall 224 to more reinforce the electrical connection.

The auxiliary member 230 may include the first member 232, the second member 234, and the third member 236. In this case, when the third member 236 couples the first wall 216 to the second wall 224, the second member 234 is fixed in close contact with between the first wall 216 and the second wall 224. Accordingly, such an auxiliary member 230 can more reinforce the electrical connection between the ground wiring on the first surface side of the substrate 110, the upper-side case 210, and the lower-side case 220.

### Third Exemplary Configuration of Auxiliary Member 230

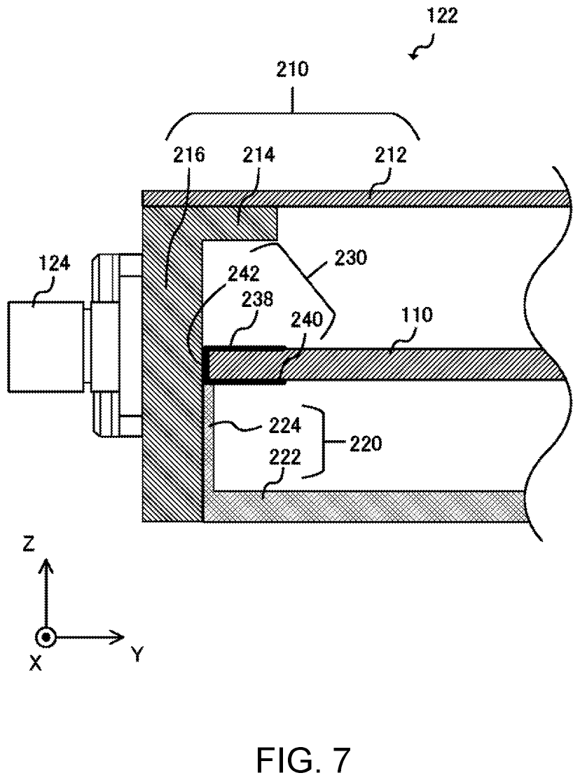

FIG. 7 illustrates a third exemplary configuration of the first shield case 122 according to the embodiment. In the first shield case 122 having the third exemplary configuration illustrated in FIG. 7, identical reference numerals are attached to ones having operations approximately identical to those of the first shield case 122 illustrated in FIG. 3. Therefore, the description will be omitted. An example that the first shield case 122 having the third exemplary configuration includes a fourth member 238, a fifth member 240, and a sixth member 242 that are conductive as the auxiliary member 230 will be described.

The fourth member 238 is disposed in contact with the first surface of the substrate 110. The fourth member 238 is electrically connected to the ground wiring of the first surface of the substrate 110. The fifth member 240 is disposed in contact with each of the second surface of the substrate 110 and the second wall 224. The fifth member 240 is electrically connected to a ground wiring of the second surface of the substrate 110. The sixth member 242 is connected to the fourth member 238 and the fifth member 240. The fourth member 238, the fifth member 240, and the sixth member 242 are, for example, integrally formed by bending one copper plate. Such a fourth member 238, a fifth member 240, and a sixth member 242 have a U-shaped integrated shape in the cross section of the surface approximately parallel to the Y-Z plane and are fixed to an end portion of the substrate 110.

Such an auxiliary member 230 can reinforce the electrical connection between the ground wirings of the first surface and the second surface of the substrate 110. The auxiliary member 230 also can reinforce the electrical connection between the ground wirings of the first surface and the second surface of the substrate 110, and the lower-side case 220. The upper-side case 210 contacts the sixth member 242 by fitting the upper-side case 210 to the lower-side case 220. This can reinforce the electrical connection between the ground wirings of the first surface and the second surface of the substrate 110, and the upper-side case 210 and the lower-side case 220.

That is, also in the first shield case 122 having the third exemplary configuration, the electrical connection between the substrate 110, the upper-side case 210, and the lower-side case 220 can be reinforced. The auxiliary member 230 may further include at least one of the first member 232, the second member 234, and the third member 236 in addition to the fourth member 238, the fifth member 240, and the sixth member 242.

The auxiliary member 230 can increase an area where the auxiliary member 230 is pressed to and brought into close contact with the second wall 224 by further including the first member 232 and the second member 234, thus further reinforcing the electrical connection with the upper-side case 210 and the lower-side case 220. The auxiliary member 230 can reinforce the electrical connection between the upper-side case 210 and the lower-side case 220 and reinforce the electrical connection between the sixth member 242 and the upper-side case 210 by further including the third member 236.

The auxiliary member 230 can more reinforce the electrical connection between the ground wirings of the first surface and the second surface of the substrate 110, and the upper-side case 210 and the lower-side case 220 by including the first member 232 to the sixth member 242 to superimpose the above-described effects. The improvement in the shield property by the auxiliary member 230 that includes the first member 232 to the sixth member 242 will be described next.

Exemplary Signal Inside Receiver 120 on which Auxiliary Member 230 is Disposed

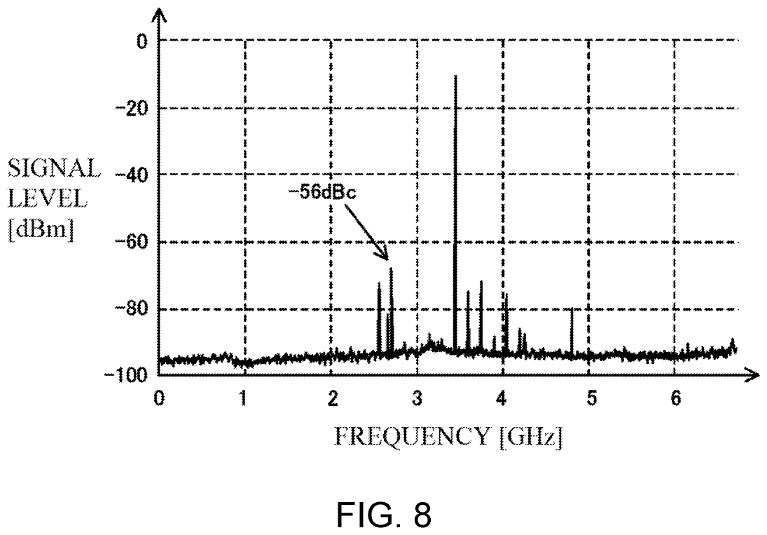

FIG. 8 illustrates an exemplary electric signal processed by the module device 100 that includes the auxiliary member 230 according to the embodiment. FIG. 8 illustrates an exemplary result when the module device 100 that includes the auxiliary member 230 executes an operation similar to that by the receiver 120 described in FIG. 2. Thus, the description of the operation of the receiver 120 is omitted here. The auxiliary member 230 is assumed to include the first member 232 to the sixth member 242. In FIG. 8, the horizontal axis indicates a frequency, and the vertical axis indicates a signal strength.

A plurality of spurious components are superimposed on a frequency spectrum illustrated in FIG. 8, besides the high frequency signal of 3.45 GHz, similarly to FIG. 2. However, it can be seen that, compared with the plurality of spurious components generated in FIG. 2, the signal strengths are reduced in all the spuriouses. For example, the signal strength of the spurious generated at 2.7 GHz is −56 dBc with respect to the signal strength of the high frequency signal of 3.45 GHz. Thus, an improvement of 16 dB or more can be confirmed. This satisfies the spurious standard that requires that a spurious strength is −40 dBc.

### Fourth Exemplary Configuration of Auxiliary Member 230

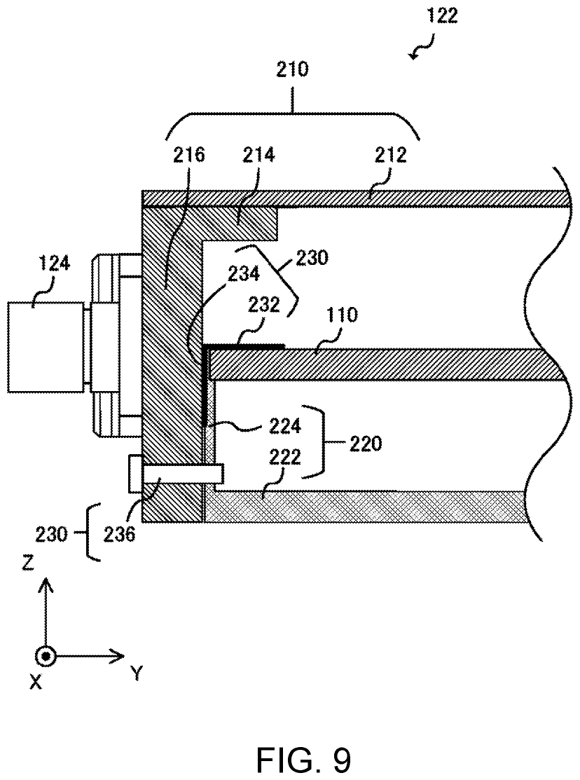

FIG. 9 illustrates a fourth exemplary configuration of the first shield case 122 according to the embodiment. In the first shield case 122 having the fourth exemplary configuration illustrated in FIG. 9, identical reference numerals are attached to ones having operations approximately identical to those of the first shield cases 122 illustrated in FIG. 3 to FIG. 6. Therefore, the description will be omitted. The first shield case 122 having the fourth exemplary configuration has an exemplary configuration obtained by combining the first shield case 122 having the first exemplary configuration with the first shield case 122 having the second exemplary configuration. That is, the first shield case 122 having the fourth exemplary configuration includes the conductive first member 232, second member 234, and third member 236 as the auxiliary member 230.

The first member 232, the second member 234, and the third member 236 have been described in FIG. 4 to FIG. 6, thus not being described here. The module device 100 can reduce the spurious of the received signal to satisfy the spurious standard as illustrated in FIG. 8 by using the first shield case 122 having the fourth exemplary configuration. A method for assembling such a module device 100 will be described next.

### Assembly Flow for Module Device 100

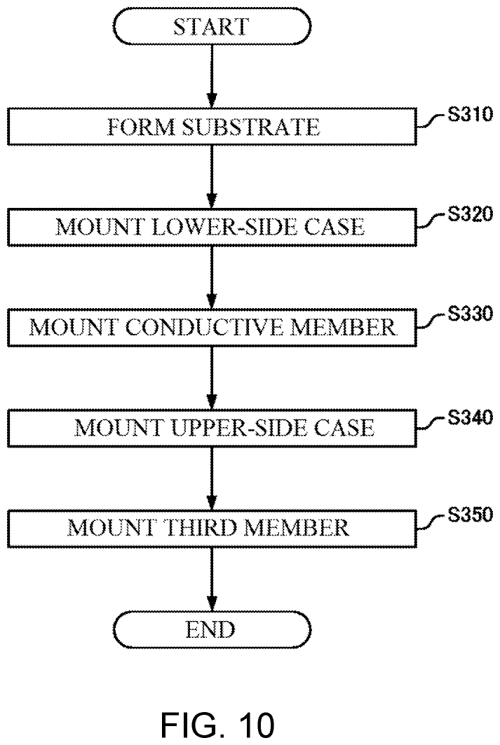

FIG. 10 illustrates an exemplary flow for assembling the module device 100 that includes the first shield case 122 having the fourth exemplary configuration. The assembly flow illustrated in FIG. 10 illustrates an example that the first shield case 122 is mounted on the substrate 110 and omits the assembly of the second shield case 132 and the like.

First, the substrate 110 is formed (S310). The substrate 110 has the first surface and the second surface on which the electronic components, the wirings, and the like are disposed, thus configuring the receiving circuit and the transmitting circuit. The detail description of a circuit and the like formed on the substrate 110 is omitted.

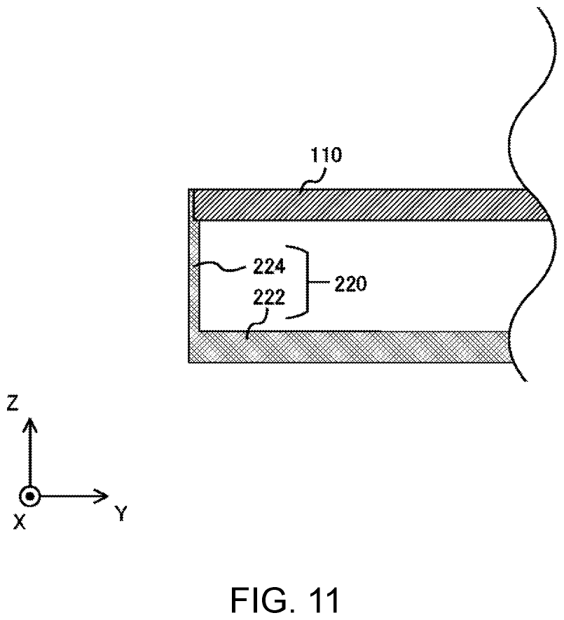

Next, the lower-side case 220 having the second wall 224 is mounted on the substrate 110 (S320). The second wall 224 extends toward the substrate 110 to be in contact with the substrate 110. The lower-side case 220 is mounted to cover at least a part of the second surface of the substrate 110. FIG. 11 illustrates an exemplary configuration of a cross section in a state where the lower-side case 220 has been mounted on the substrate 110 according to the embodiment. Instead of this example, when the auxiliary member 230 having the third exemplary configuration illustrated in FIG. 7 is mounted, the auxiliary member 230 is mounted on the substrate 110 and then, the lower-side case 220 is mounted on this substrate 110. In this phase, a lower-side case of the second shield case 132 may be mounted on the substrate 110.

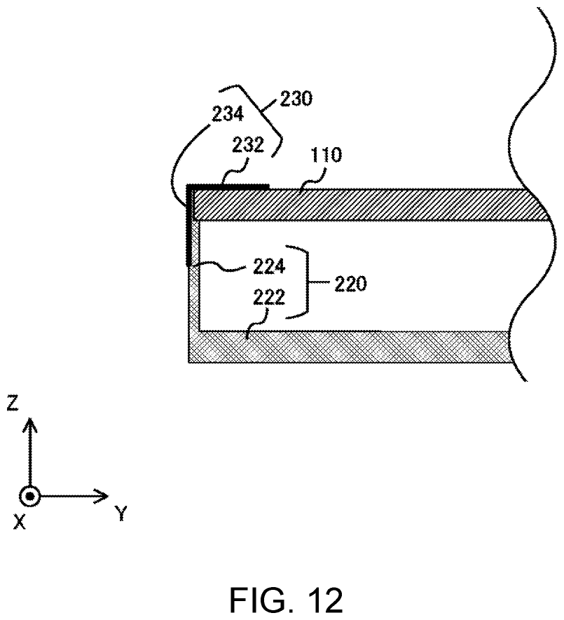

Next, a conductive member is mounted to be in contact with the substrate 110 and the lower-side case 220 (S330). Here, the conductive member is a part of the auxiliary member 230 and includes, for example, the first member 232 and the second member 234. In this phase, the first member 232 and the second member 234 assist the electrical connection between the substrate 110 and the second wall 224. FIG. 12 illustrates an exemplary configuration of a cross section in a state where the conductive member has been mounted on the substrate 110 and the lower-side case 220 according to the embodiment.

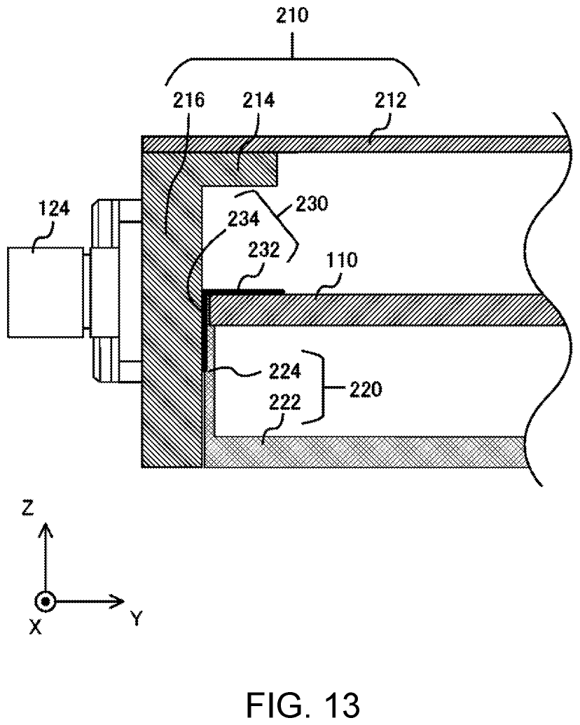

Next, the upper-side case 210 having the first wall 216 is mounted on the substrate 110 and the lower-side case 220 (S340). The upper-side case 210 is mounted to cover at least a part of the first surface of the substrate 110. FIG. 13 illustrates an exemplary configuration of a cross section in a state where the upper-side case 210 has been mounted on the substrate 110 and the lower-side case 220 according to the embodiment. When the upper-side case 210 has been mounted, the wiring of the first surface of the substrate 110 may be connected to the input connector 124 by opening the lid 212. Adjustment, wiring, and the like of the circuit of the first surface of the substrate 110 may be performed. In this phase, an upper-side case of the second shield case 132 may be mounted on the substrate 110 and the lower-side case of the second shield case 132.

Next, the third member 236 is mounted on the upper-side case 210 and the lower-side case 220 (S350). The third member 236 is mounted to pass through the first wall 216 and the second wall 224. For example, the third member 236 is a screw to assist the electrical connection between the first wall 216 and the second wall 224 and fix the first wall 216, the second member 234, and the second wall 224. Thus, the first member 232 and the second member 234 assist the electrical connection between the substrate 110, the first wall 216, and the second wall 224. An exemplary configuration of a cross section in a state where the third member 236 has been mounted on the upper-side case 210 and the lower-side case 220 is approximately identical to that in FIG. 9.

As described above, the first shield case 122 of the module device 100 according to the embodiment can be easily assembled without including a complicated process. The first shield case 122 can be easily assembled concurrently with the assembly of the second shield case 132. Accordingly, generation of characteristics change caused by the assembly can be reduced, thus allowing a worker or the like to stably assemble the module device 100.

An example that, in the above-described module device 100 according to the embodiment, the first shield case 122 of the receiver 120 includes the auxiliary member 230 to ensure the reduction in the spurious of the received signal has been described. However, such an improvement in the shield property is not limited to the receiver 120. The auxiliary member 230 of the module device 100 can be similarly applied to the second shield case 132 of the transmitter 130 to also improve the shield property of the transmitter 130.

When the auxiliary members 230 are disposed on the receiver 120 and the transmitter 130, the first member 232 and second member 234 and the fourth member 238 fifth member 240 and sixth member 242 may be individually disposed on the receiver 120 and the transmitter 130 respectively, or instead of this, may be disposed as a common integrated member. Also when a plurality of receivers 120 and/or transmitters 130 are disposed on the module device 100, similarly, a part of the auxiliary member 230 may be disposed as the common integrated member. Thus, communalizing the member mounted on the module device 100 can further stabilize the ground potential. An assembly man-hour of the worker or the like can be also further reduced.

As described above, with the module device 100 according to the embodiment, even when the components for high frequency are mounted on both surfaces of the substrate 110, the use of the auxiliary member 230 can improve spurious characteristics of the transmission system and the reception system, isolation characteristics between adjacent channels, and the like. The auxiliary member 230 can be mounted on the module device 100 with an easy work by the worker or the like. That is, the use of the auxiliary member 230 can facilitate the assembly of the module device 100, thus ensuring production of this module device 100 by reducing the man-hour of the worker or the like.

In the first aspect of this disclosure, the auxiliary member may include a conductive first member disposed in contact with the first surface of the substrate and a conductive second member disposed in contact with the second wall. The first member and the second member may have an L-shaped integrated shape, and the first member may be electrically connected to a ground wiring of the first surface of the substrate.

The first wall may be partially parallel to the second wall, and the auxiliary member may include a conductive third member that couples the first wall to the second wall. The third member may be a screw that passes through the first wall and the second wall.

The auxiliary member may include a conductive fourth member disposed in contact with the first surface of the substrate, a conductive fifth member disposed in contact with each of the second surface of the substrate and the second wall, and a conductive sixth member that connects the fourth member to the fifth member. The fourth member may be electrically connected to the ground wiring of the first surface of the substrate, and the fourth member, the fifth member, and the sixth member may have a U-shaped integrated shape and are fixed to an end portion of the substrate.

The substrate may include a receiver that receives an electric signal from an outside and a transmitter that transmits an electric signal to the outside, the receiver and the transmitter may include the auxiliary member, and the auxiliary member may be partially disposed as a common integrated member on the receiver and the transmitter.

According to a second aspect of this disclosure, there is provided a method for assembling a module device. The method includes forming a substrate, preparing an upper-side case that has a first wall and covers at least a part of a first surface of the substrate, preparing a lower-side case that has a second wall that extends toward the substrate and is in contact with the substrate, the lower-side case covering at least a part of a second surface on a side opposite to the first surface of the substrate, mounting the lower-side case on the substrate, mounting a conductive member to be in contact with the substrate and the lower-side case, mounting the upper-side case on the substrate and the lower-side case, and mounting a third member to pass through the first wall and the second wall.

The embodiment provides an effect that reduces the complicated assembly for the module device and improves the shield property.

While this disclosure has been described above using the embodiments, the technical scope of this disclosure is not limited to the scope described in the above-described embodiments, and various modifications and changes are possible within the scope of the gist. For example, this disclosure can be functionally or physically distributed and integrated in any unit for all or a part thereof. Additionally, a new embodiment created by any combination of the plurality of embodiments is also included in the embodiment of this disclosure. Effects of the new embodiment created by the combination also include the effects of the original embodiments.

What is claimed is:

1. A module device comprising:
a substrate;
an upper-side case that has a first wall and covers at least a part of a first surface of the substrate;
a lower-side case that has a second wall that extends to the substrate and is in contact with the substrate, the lower-side case covering at least a part of a second surface on a side opposite to the first surface of the substrate; and
an auxiliary member that assists an electrical connection between the second wall and at least one of the substrate and the first wall, wherein
the upper-side case is fitted to the lower-side case across the substrate to house at least a part of the substrate.

2. The module device according to claim 1, wherein
the auxiliary member includes:
a conductive first member disposed in contact with the first surface of the substrate; and
a conductive second member disposed in contact with the second wall.

3. The module device according to claim 2, wherein
the first member and the second member have an L-shaped integrated shape, and
the first member is electrically connected to a ground wiring of the first surface of the substrate.

4. The module device according to claim 1, wherein
the first wall is partially parallel to the second wall, and
the auxiliary member includes a conductive third member that couples the first wall to the second wall.

5. The module device according to claim 4, wherein
the third member is a screw that passes through the first wall and the second wall.

6. The module device according to claim 1, wherein
the auxiliary member includes:
a conductive fourth member disposed in contact with the first surface of the substrate;
a conductive fifth member disposed in contact with each of the second surface of the substrate and the second wall; and
a conductive sixth member that connects the fourth member to the fifth member.

7. The module device according to claim 6, wherein
the fourth member is electrically connected to the ground wiring of the first surface of the substrate, and
the fourth member, the fifth member, and the sixth member have a U-shaped integrated shape and are fixed to an end portion of the substrate.

8. The module device according to claim 1, wherein
the substrate includes:
a receiver that receives an electric signal from an outside; and
a transmitter that transmits an electric signal to the outside,
the receiver and the transmitter include the auxiliary member, and
the auxiliary member is partially disposed as a common integrated member on the receiver and the transmitter.

9. A method for assembling a module device, comprising:
forming a substrate;
preparing an upper-side case that has a first wall and covers at least a part of a first surface of the substrate;
preparing a lower-side case that has a second wall that extends to the substrate and is in contact with the substrate, the lower-side case covering at least a part of a second surface on a side opposite to the first surface of the substrate;
mounting the lower-side case on the substrate;
mounting a conductive member to be in contact with the substrate and the lower-side case;
mounting the upper-side case on the substrate and the lower-side case; and
mounting a third member to pass through the first wall and the second wall.
